(19) United States
(12) Patent Application Publication
(10) Pub. No.: US 2010/0325913 A1
(43) Pub. Date: Dec. 30, 2010

(54) SUBSTRATE PROCESSING METHOD AND SUBSTRATE PROCESSING APPARATUS

(76) Inventors: Xinming WANG, Tokyo (JP); Kazuo Yamauchi, Tokyo (JP); Akira Kodera, Tokyo (JP); Tsukuru Suzuki, Tokyo (JP); Yasushi Toma, Tokyo (JP); Takayuki Saito, Tokyo (JP); Hirokuni Hiyama, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 12/821,456

(22) Filed: Jun. 23, 2010

(30) Foreign Application Priority Data
Jun. 29, 2009 (JP) 2009-153289

(51) Int. Cl. F26B 7/00

(52) U.S. Cl. 34/423; 34/69

(57) ABSTRACT

A substrate processing method dose not use or only use the least possible amount of an organic solvent, and can quickly and completely remove a liquid from a wet substrate surface without allowing the liquid to remain on the substrate surface. The substrate processing method for drying a substrate surface which is wet with a liquid, includes: removing the liquid from the substrate surface and sucking the liquid together with its surrounding gas into a gas/liquid suction nozzle, disposed opposite the substrate surface, while relatively moving the gas/liquid suction nozzle and the substrate parallel to each other; and blowing a dry gas from a dry gas supply nozzle, disposed opposite the substrate surface, toward that area of the substrate surface from which the liquid has been removed while relatively moving the dry gas supply nozzle and the substrate parallel to each other.

### BACKGROUND OF THE INVENTION

1. Field of the Invention

The present invention relates to a substrate processing method and a substrate processing apparatus for cleaning and drying a surface of a substrate, such as a semiconductor wafer, a substrate for a liquid crystal display or a plasma display, an optical disk substrate, or the like. An exemplary usable substrate is a disk-shaped silicon substrate having a thickness of not less than 200 mm, for example 200 mm, 300 mm or 450 mm, and a thickness of 0.6 mm to 1.2 mm.

2. Description of the Related Art

For semiconductor devices, which are becoming more and more highly integrated, besides the demand for higher integration, there is a demand to manufacture semiconductor devices at a high yield. A high cleanliness of a substrate surface is especially necessary to achieve a high device yield. There is, therefore, an increasingly great demand for a highly clean substrate surface. In a semiconductor device manufacturing process, under the above background, cleaning of a substrate surface is carried out in various process steps. To decrease an electrical capacitance of a dielectric film, a low-k film (low-dielectric constant film) has recently been used as a dielectric film. A surface of a low-k film is hydrophobic. Thus, the use of a low-k film has led to a cleaning step which cleans a substrate surface including a hydrophobic surface.

The following problems arise when cleaning and drying a surface of a substrate, such as a semiconductor wafer, having a low-k film as a dielectric film: When wet processing, such as liquid chemical processing or rinsing, is carried out on a substrate surface including a hydrophobic surface, a continuous liquid film is unlikely to be formed on the substrate surface and it is highly possible that the substrate surface is partly exposed to the atmosphere without being covered with a liquid film. When wet processing is carried out on the substrate surface under these circumstances, part of a processing liquid is likely to remain as liquid droplets on the exposed substrate surface. Upon evaporation of the liquid droplets remaining on the substrate surface, a solid reaction product, which causes the formation of watermarks, may remain on the substrate surface. Such watermarks formed on the substrate surface may lower the yield of the product.

With semiconductor wafers becoming larger, an increasing number of one-by-one processing type of apparatuses are used for wet processing in a semiconductor device manufacturing process. Widely known one-by-one wet processing apparatuses or units for semiconductor wafers include those which use a spin drying method (see Japanese Patent No. 2,922,754 and Japanese Patent Laid-Open Publication No. 2003-31545).

In a one-by-one wet processing apparatus or unit using a spin drying method, a substrate surface is cleaned with a liquid chemical by supplying the liquid chemical to the substrate surface while rotating the substrate, held by a substrate holder such as a spin chuck, at a high speed, and the substrate surface is then cleaned with a cleaning liquid, such as ultrapure water, to wash away the liquid chemical on the substrate surface. Thereafter, the substrate is spin-dried by rotating the substrate at a higher speed to force the cleaning liquid off the substrate surface. However, the spin drying method, which involves high-speed rotation of a substrate to dry the substrate, has the drawback that a large amount of mist (minute liquid droplets), scattering from a substrate due to the high-speed rotation of the substrate, re-attaches to the surface of the substrate, which can cause the formation of watermarks on the substrate surface.

Especially when drying a hydrophobic substrate surface having a low-k film by using the spin drying method, a continuous liquid film on the substrate surface is likely to break into liquid string-like segments or liquid droplets in the course of drying. Consequently, the substrate surface becomes partly exposed to the atmosphere and semi-dried surface regions are formed. When the liquid droplets move to the semi-dried surface regions, smaller liquid droplets remain at the former droplet sites. Watermarks are likely to be formed after the remaining liquid droplets dry out.

Various methods for drying a substrate surface without producing watermarks on the substrate surface have recently been proposed. Such methods include an IPA vapor drying method which involves replacement of water on a substrate surface with IPA (isopropyl alcohol) in an IPA vapor, a Marangoni drying method which involves pulling up a substrate from water into an IPA vapor (see U.S. Pat. Nos. 6,746,544, 7,252,098 and 6,926,590), and a Rotagoni drying method which involves spraying an IPA vapor to a vapor-liquid interface while rotating a substrate at a low speed (see U.S. Pat. Nos. 6,491,764, 6,568,408 and 6,754,980). These methods, however, all entail the problem of organic matter remaining on a substrate surface and the safety and environmental problem associated with the use of the flammable solvent. Therefore, a demand exists for development of a drying method to take the place of the conventional drying methods using IPA, or a drying method that can minimize the amount of IPA used.

Mechanical drying methods, such as an air blowing method and a suction method, have been proposed as drying methods which use no organic solvent such as IPA. A drying method that employs the air blowing method (see Japanese Patent Laid-Open Publication No. 2004-146414) entails the problem that liquid droplets, scattering from a substrate surface by blowing air, re-attach to the substrate surface, and the problem that a liquid film or liquid droplets, moving on the substrate surface by the force of blowing air, break into small droplets during the movement and remain on the substrate surface. A method is also known which comprises bringing a front end of a suction nozzle into contact with a liquid on a substrate surface, and continuously sucking the liquid into the suction nozzle to remove the liquid on the substrate surface (see Japanese Patent Laid-Open Publication Nos. 6-342782 and 2007-12653). Though this method can effectively remove, through suction by the suction nozzle, most of a continuous liquid film having a certain level of thickness, it is difficult to suck and remove a thin liquid film or minute liquid droplets remaining on a substrate surface.

Thus, while the currently-known drying methods which use no organic solvent, such as IPA, can effectively remove a visible liquid film or visible liquid droplets, for example, a liquid film having a thickness of not less than a few mm or liquid droplets having a diameter of not less than a few mm, it is difficult for the conventional methods to remove minute liquid droplets which can cause the formation of watermarks.

Further, a drying method has been proposed which comprises supplying a liquid, such as ultrapure water, to a gap between a substrate surface and a substrate-facing surface of a plate, disposed close to and opposite the substrate surface, and holding the liquid in a liquid-tight state, and supplying an organic solvent, such as IPA or HFE (hydrofluoroether), to the substrate surface to dry the substrate surface through physical replacement of the liquid with the organic solvent or dissolution between the two liquids (see Japanese Patent Laid-Open Publication No. 2008-78329). This drying method, which involves replacement of the liquid, held tightly between the substrate surface and the plate, with an organic solvent, should necessitate the use of a considerable amount of the organic solvent.

### SUMMARY OF THE INVENTION

The present invention has been made in view of the above situation in the related art. It is therefore an object of the present invention to provide a substrate processing method and a substrate processing apparatus which do not use or only use the least possible amount of an organic solvent, and which can quickly and completely remove a liquid, including an invisibly thin liquid film or minute liquid droplets, from a wet substrate surface without allowing the liquid to remain on the substrate surface, thereby minimizing the formation of watermarks.

In order to achieve the above object, the present invention provides a substrate processing method for drying a substrate surface which is wet with a liquid, comprising: removing the liquid from the substrate surface and sucking the liquid together with its surrounding gas into a gas/liquid suction nozzle, disposed opposite the substrate surface, while relatively moving the gas/liquid suction nozzle and the substrate parallel to each other; and blowing a dry gas from a dry gas supply nozzle, disposed opposite the substrate surface, toward that area of the substrate surface from which the liquid has been removed while relatively moving the dry gas supply nozzle and the substrate parallel to each other.

According to this method, a fast gas stream is created over the substrate surface and in the vicinity of the suction opening of the gas/liquid suction nozzle, and the fast gas stream applies a shear stress to the interface between the gas stream and a liquid droplet or a liquid film on the substrate surface. Liquid droplets, which have been separated from the liquid droplet or liquid film, are carried by the fast gas stream, and are sucked into the gas/liquid suction nozzle. Thus, according to this method, the liquid can be removed from the substrate surface by utilizing the shear stress acting on the gas-liquid interface. There is, therefore, no need to bring the suction opening of the gas/liquid suction nozzle into contact with the liquid. A liquid film or liquid droplets having a visible level of size, e.g., a thick liquid film having a thickness of more than about 500 μm or large liquid droplets having a diameter of more than about 500 μm, can be completely removed from the substrate surface. Even when invisible minute liquid droplets, having a smaller diameter than the above liquid droplets, remain on the substrate surface, the rate of evaporation of the liquid droplets is accelerated and the liquid droplets evaporate instantaneously due to the flow of the dry gas supplied from the dry gas supply nozzle to the substrate surface. An invisibly thin liquid film, because of its large specific surface area, likewise evaporates instantaneously. Thus, this method can prevent the liquid from remaining on the substrate surface, thereby preventing the formation of watermarks on the substrate surface.

Preferably, the gas/liquid suction nozzle and the dry gas supply nozzle are moved integrally relative to the substrate, with the gas/liquid suction nozzle being positioned anterior to the dry gas supply nozzle in the direction of their movement relative to the substrate.

This makes it possible to dry the substrate surface under stable conditions while keeping the relative position between the gas/liquid suction nozzle and the dry gas supply nozzle constant.

The speed of the movement of the gas/liquid suction nozzle and the dry gas supply nozzle relative to the substrate is preferably 0.01 m/s to 0.07 m/s.

When the speed of the movement of the gas/liquid suction nozzle and the dry gas supply nozzle relative to the substrate is low, the liquid can be effectively removed from the substrate surface by the fast gas stream and through the evaporation of the liquid, which is promoted by the flow of the dry gas. However, when the speed of the relative movement is too low, in addition to the need for a longer processing time, the liquid removal effect can even decrease due to breakage of a liquid film, lying in the vicinity of the suction opening, before it is separated from the substrate surface. On the other hand, when the speed of the relative movement is too high, the liquid can remain on the substrate surface without being completely removed. In view of the liquid removal effect and the processing time taken to dry the substrate, the speed of the movement of the gas/liquid suction nozzle and the dry gas supply nozzle relative to the substrate is preferably 0.01 m/s to 0.07 m/s, more preferably 0.02 m/s to 0.05 m/s.

Preferably, a liquid is supplied toward the substrate surface from a liquid supply nozzle at a position posterior to the gas/liquid suction nozzle and anterior to the dry gas supply nozzle in the direction of their movement relative to the substrate.

Thus, a liquid is supplied from the liquid supply nozzle toward the substrate surface, and the liquid supplied is sacked and removed into the gas/liquid suction nozzle. This can more definitively prevent liquid droplets from remaining in a region between the liquid supply nozzle and the gas/liquid suction nozzle and re-attaching to the substrate surface.

Preferably, the gas/liquid suction nozzle, the dry gas supply nozzle and the liquid supply nozzle are moved integrally relative to the substrate, with the gas/liquid suction nozzle being positioned anterior to the dry gas supply nozzle and the liquid supply nozzle being positioned between the gas/liquid suction nozzle and the dry gas supply nozzle in the direction of their movement relative to the substrate.

This makes it possible to dry the substrate surface under stable conditions while keeping the relative position between the gas/liquid suction nozzle, the dry gas supply nozzle and the liquid supply nozzle constant, and more definitively preventing liquid droplets from remaining in a region between the liquid supply nozzle and the gas/liquid suction nozzle.

The speed of the movement of the gas/liquid suction nozzle, the dry gas supply nozzle and the liquid supply nozzle relative to the substrate is preferably 0.01 m/s to 0.07 m/s, more preferably 0.02 m/s to 0.05 m/s.

A water-soluble organic solvent may be supplied toward the substrate surface from an organic solvent supply nozzle at a position posterior to the gas/liquid suction nozzle in the direction of its movement relative to the substrate.

Even when minute liquid droplets remain on the substrate surface, the water-soluble organic solvent, supplied from the organic solvent supply nozzle, can be dissolved in the minute liquid droplets to accelerate the rate of evaporation of the minute liquid droplets. This makes it possible to dry the substrate while preventing the formation of watermarks. The water-soluble organic solvent can be used only in such an amount as to dissolve it in the minute liquid droplets remaining on the substrate surface. Thus, the amount of the water-soluble organic solvent used can be significantly reduced compared to the conventional method.

Preferably, the gas/liquid suction nozzle, the dry gas supply nozzle and the organic solvent supply nozzle are moved integrally relative to the substrate, with the gas/liquid suction nozzle being positioned anterior to the dry gas supply nozzle and the organic solvent supply nozzle, and one of the dry gas supply nozzle and the organic solvent supply nozzle being positioned anterior to the other in the direction of their movement relative to the substrate.

This makes it possible to dry the substrate surface under stable conditions while keeping the relative position between the gas/liquid suction nozzle, the dry gas supply nozzle and the organic solvent supply nozzle constant, and more definitively preventing liquid droplets from remaining on the substrate surface.

The speed of the movement of the gas/liquid suction nozzle, the dry gas supply nozzle and the organic solvent supply nozzle relative to the substrate is preferably 0.01 m/s to 0.07 m/s, more preferably 0.02 m/s to 0.05 m/s.

Preferably, the water-soluble organic solvent is IPA (isopropyl alcohol), and the IPA vapor concentration is less than 2.2%.

The lower flash point of isopropyl alcohol (IPA) is about 12° C., and the saturated vapor concentration at that temperature, determined from the saturated vapor pressure-temperature relation, is about 2.2%. Therefore, when IPA is used as the water-soluble organic solvent, it is preferably used at a vapor concentration of less than 2.2% for safety reasons.

A gap distance between the suction opening of the gas/liquid suction nozzle and the substrate surface is preferably 1 mm to 4 mm.

The smaller the gap distance between the suction opening of the gas/liquid suction nozzle and the substrate surface, the larger is a shear stress which acts on the interface between a liquid film or liquid droplet on the substrate surface and a gas stream. However, in view of deformation of the substrate and the accuracy of a position adjustment mechanism, the gap distance between the suction opening of the gas/liquid suction nozzle and the substrate surface is preferably not less than 1 mm. On the other hand, in view of the minimum shear stress that can break a liquid film into liquid droplets, the gap distance between the suction opening of the gas/liquid suction nozzle and the substrate surface is preferably not more than 4 mm. The gap distance between the suction opening of the gas/liquid suction nozzle and the substrate surface is more preferably 1.5 mm to 2.5 mm.

Preferably, the suction flow rate is controlled so that a gas flows along the substrate surface at an average flow speed of 60 m/s to 140 m/s, and is sucked into the gas/liquid suction nozzle.

By thus allowing a gas to flow along the substrate surface at an average flow speed of 60 m/s to 140 m/s and to be sucked into the gas/liquid suction nozzle, a shear stress, which is sufficient to remove a liquid film from the substrate surface and to break the liquid film into liquid droplets that will be sucked into the gas/liquid suction nozzle, can be obtained. The suction flow rate is more preferably controlled so that a gas flows along the substrate surface at an average flow speed of 65 m/s to 95 m/s, and is sucked into the gas/liquid suction nozzle.

Preferably, the dry gas is an inert gas, and the relative humidity of the dry gas is not more than the relative humidity of the atmosphere.

The use of a dry gas, having a relative humidity which is not more than the relative humidity of the atmosphere, can more effectively evaporate minute liquid droplets or liquid films remaining on the substrate surface. Taking account of the production cost of an inert gas having a low relative humidity and the evaporation promoting effect, it is preferred to use a dry gas having such a relative humidity as to make the relative humidity of the atmosphere 1% to 40%, more preferably 5% to 10% in the vicinity of a dry gas supply opening.

Preferably, a replenishing liquid for the liquid on the substrate surface is supplied to the substrate surface at an anterior position in the direction of the movement of the gas/liquid suction nozzle relative to the substrate.

The replenished liquid on the substrate surface will be taken to form a continuous film-like liquid (liquid film) which easily removes from the substrate surface when it receives a shear stress applied by the fast gas stream. Thus, the liquid (liquid film) can be more effectively removed from the substrate surface. When the liquid on the substrate surface is a liquid chemical, the replenishing liquid may be a liquid chemical having substantially the same components. When the liquid on the substrate surface is rinsing ultrapure water, the replenishing liquid may be ultrapure water having substantially the same level of purity.

The present invention also provides a substrate processing apparatus for drying a substrate surface which is wet with a liquid, comprising: a gas/liquid suction nozzle, disposed opposite the substrate surface, for removing the liquid from the substrate surface and sucking in the liquid together with its surrounding gas; a dry gas supply nozzle for blowing a dry gas toward that area of the substrate surface from which the liquid has been removed; and a movement mechanism for relatively moving the gas/liquid suction nozzle and the substrate parallel to each other and relatively moving the dry gas supply nozzle and the substrate parallel to each other.

According to this apparatus thus constructed, a fast gas stream can be created in the vicinity of a suction opening of the gas/liquid suction nozzle, and a liquid film or liquid droplets having a visible level of size can be removed from the substrate surface by the fast gas stream and sucked into the gas/liquid suction nozzle. In addition, by blowing a dry gas toward that area of the substrate surface from which the liquid has been removed, liquid droplets remaining in the area can be evaporated, thereby drying the substrate surface.

Preferably, the gas/liquid suction nozzle and the dry gas supply nozzle are provided in a nozzle unit, and the movement mechanism is configured to move the nozzle unit parallel to the substrate.

This makes it possible to dry the substrate surface under stable conditions while keeping the relative position between the gas/liquid suction nozzle and the dry gas supply nozzle constant.

Preferably, the substrate processing apparatus further comprises a liquid supply nozzle for supplying a liquid toward the substrate surface at a position posterior to the gas/liquid suction nozzle and anterior to the dry gas supply nozzle in the direction of their movement relative to the substrate.

Preferably, the gas/liquid suction nozzle, the dry gas supply nozzle and the liquid supply nozzle are provided in a nozzle unit, and the movement mechanism is configured to move the nozzle unit parallel to the substrate.

The substrate processing apparatus may further comprise an organic solvent supply nozzle for supplying a water-soluble organic solvent to the substrate surface at a position posterior to the gas/liquid suction nozzle in the direction of its movement relative to the substrate. Preferably in this case, the gas/liquid suction nozzle, the dry gas supply nozzle and the organic solvent supply nozzle are provided in a nozzle unit, and the movement mechanism is configured to move the nozzle unit parallel to the substrate.

Preferably, the organic solvent supply nozzle is inclined at 45° to 90° with respect to the substrate surface.

It has been confirmed that the rate of evaporation of liquid droplets can be increased by making the organic solvent supply nozzle inclined at 45° to 90° with respect to the substrate surface.

Preferably, the substrate processing apparatus further comprises a replenishing liquid nozzle for supplying a replenishing liquid for the liquid on the substrate surface to the substrate surface at an anterior position in the direction of the movement of the gas/liquid suction nozzle relative to the substrate.

Preferably, the gas/liquid suction nozzle is provided plurally, and the gas/liquid suction nozzles have slit-like suction openings arranged in series.

Thus, the entire substrate surface is divided into a plurality of zonal suction areas arranged linearly. The liquid lying in each suction area is sacked and removed into a suction opening of each gas/liquid suction nozzle while liquid droplets remaining in the suction area is dried off by the dry gas. In this manner, the liquid can be removed from the entire substrate surface.

The present invention makes it possible to quickly and completely remove a liquid, including an invisibly thin liquid film or minute liquid droplets, from a wet substrate surface without allowing the liquid to remain on the substrate surface, thereby minimizing the formation of watermarks. Furthermore, according to the present invention, an organic solvent may not be used, or can be used in a significantly reduced amount compared to the conventional method.

### BRIEF DESCRIPTION OF THE DRAWINGS

FIG. 1 is a schematic plan view of a substrate processing apparatus, configured as a drying unit, according to an embodiment of the present invention;

FIG. 2 is a vertical sectional front view of the drying unit shown in FIG. 1;

FIG. 3 is a schematic cross-sectional view of a front surface-side nozzle unit of the drying unit shown in FIG. 1;

FIG. 4 is a graph showing the relationship between evaluation value and suction flow speed;

FIG. 5 is a graph showing the relationship between evaluation value and N₂ gas flow rate;

FIG. 6 is an enlarged view of a portion of the graph of FIG. 5, showing the relationship between evaluation value and N₂ gas flow rate;

FIG. 7 is a graph showing the relationship between evaluation value and the relative humidity of gas atmosphere in the vicinity of a gas supply opening;

FIG. 8 is a graph showing the relationship between evaluation value and relative speed;

FIG. 9 is a graph showing the relationship between evaluation value and gap distance;

FIG. 10 is a diagram equivalent to FIG. 3, illustrating an example of the use of a front surface-side nozzle unit of a drying unit according to another embodiment of the present invention;

FIG. 11 is a diagram equivalent to FIG. 3, illustrating another example of the use of the front surface-side nozzle unit shown in FIG. 10;

FIG. 12 is a diagram equivalent to FIG. 3, illustrating a front surface-side nozzle unit of a drying unit according to yet another embodiment of the present invention;

FIG. 13 is a graph showing the relationship between evaporation rate and an angle formed between the direction of emission of an organic solvent vapor and a substrate surface;

FIG. 14 is a schematic plan view of a substrate processing apparatus, configured as a drying unit, according to yet another embodiment of the present invention, illustrating the apparatus immediately after the start of movement of a front surface-side nozzle unit;

FIG. 15 is a schematic plan view of the substrate processing apparatus shown in FIG. 14, illustrating the apparatus immediately before the end of movement of the front surface-side nozzle unit; and

FIG. 16 is an overall plan view of a polishing apparatus incorporating a drying unit (substrate processing apparatus) according to the present invention.

### DETAILED DESCRIPTION OF THE PREFERRED EMBODIMENTS

Preferred embodiments of the present invention will now be described with reference to the drawings. In the following description, the same reference numerals are used for the same or equivalent members or elements, and a duplicate description thereof will be omitted.

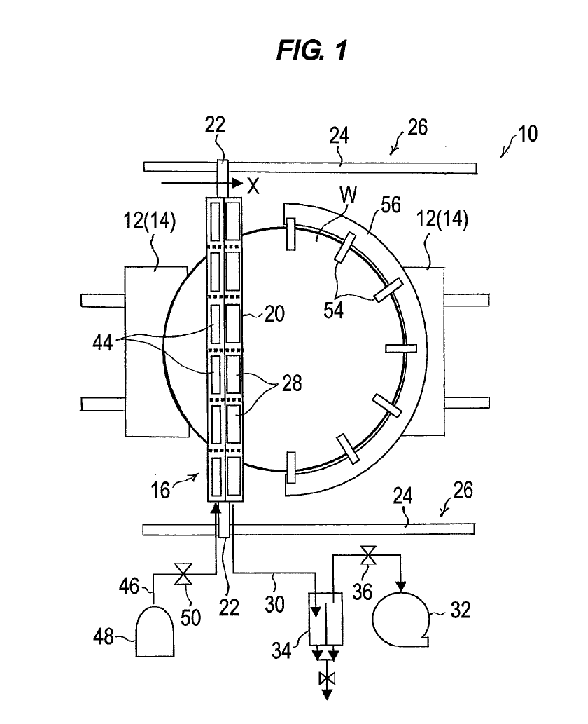

FIGS. 1 through 3 show a substrate processing apparatus, configured as a drying unit, according to an embodiment of the present invention. The drying unit (substrate processing apparatus) 10 includes a substrate holder 14 comprised of a pair of clampers 12 disposed opposite to each other and which can be moved closer to or away from each other and can detachably hold a substrate W, such as a semiconductor wafer, with a front surface (surface to be processed) facing upwardly, a front surface-side nozzle unit 16 disposed above the front surface (upper surface) of the substrate W held by the substrate holder 14 and which horizontally moves parallel to the front surface, and a back surface-side nozzle unit 18 disposed below a back surface (lower surface) of the substrate W held by the substrate holder 14 and which horizontally moves parallel to the back surface.

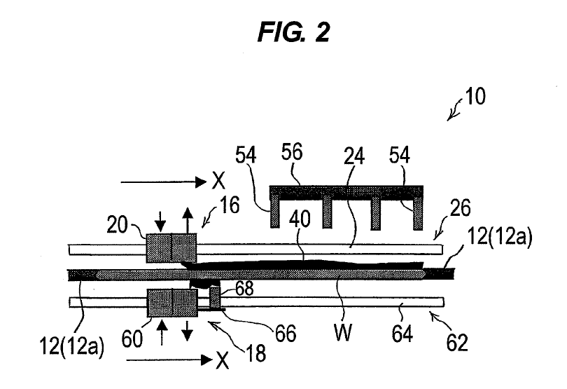

As shown in FIG. 2, a thickness of the clamp portion 12a of each clamper 12 is substantially equal to a thickness of the substrate W so that when the substrate W is held by the clamp portions 12a, the front surface of the substrate W will be flush with upper surfaces of the clamp portions 12a and the back surface of the substrate W will be flush with lower surfaces of the clamp portions 12a, and therefore the clamp portions 12a will not interfere with processing of the substrate W. Though the substrate holder 14 of this embodiment has the pair of clampers 12, it is also possible to use a substrate holder having three of more clampers, for example, four clampers circumferentially arranged at 90° intervals.

The front surface-side nozzle unit 16 has a body portion 20 linearly extending the full length of the diameter of the substrate W, and rod-like support portions 22 coupled to both ends of the body portion 20. The movement mechanisms 26 are disposed on both side of the substrate W held by the substrate holder 14 and include the carriers 24, such as a movable endless chain or belt. Each support portion 22 is coupled to the carrier 24 of each movement mechanism 26. Thus, as the carriers 24 of the movement mechanisms 26 travel synchronously during processing of the substrate W, the front surface-side nozzle unit 16 moves from a standby position horizontally in one direction, the X-direction shown in FIGS. 1 through 3, parallel to the front surface of the substrate W held by the substrate holder 14 while processing and, after completion of the processing, returns to the standby position. Each movement mechanism 26 also includes a vertical movement mechanism (not shown) for vertically moving the carrier 24.

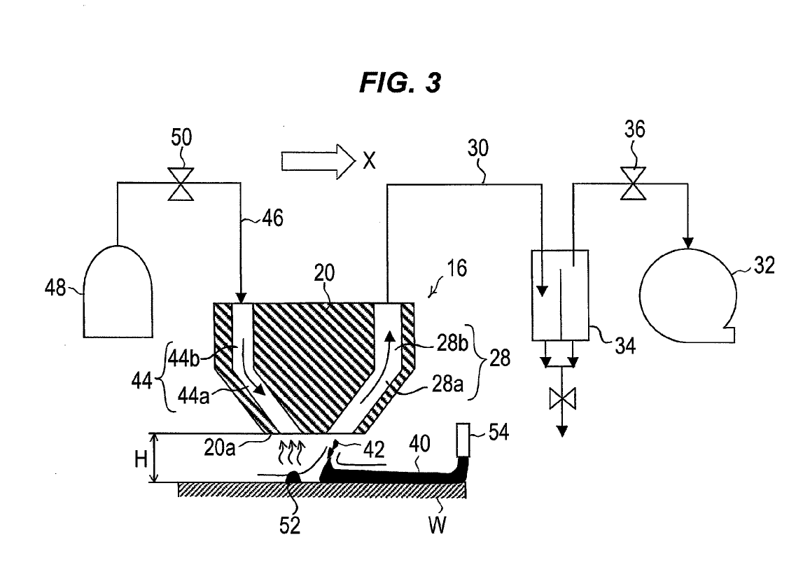

As shown in FIG. 3, a lower surface of the body portion 20 of the front surface-side nozzle unit 16 provides a flat substrate-facing surface 20a which is parallel to the front surface of the substrate W held by the substrate holder 14. Gas/liquid suction nozzles 28, each of which vertically penetrates through the body portion 20 and opens onto the substrate-facing surface 20a, are provided within the body portion 20. Each gas/liquid suction nozzle 28 has an inclined portion 28a which is inclined toward the direction (X-direction) of the nozzle movement and extends obliquely upward from the substrate-facing surface 20a so that a gas/liquid flow being sucked has at least a velocity component vertical to the front surface of the substrate W, and a vertical portion 28b which communicates with the inclined portion 28a and extends vertically. The gas/liquid suction nozzles 28 are each connected via a suction line 30 to a blower 32 as a suction section. A gas-liquid separator 34 and a suction flow control valve 36 are interposed in the suction line 30.

With this construction, when the blower 32 is activated while moving the front surface-side nozzle unit 16 horizontally in the movement direction (X-direction), a fast gas stream is created in the vicinity of a suction opening, facing the front surface of the substrate W, of each gas/liquid suction nozzle 28, and the fast gas stream applies a shear stress especially to the interface between the gas stream and a continuous film-like liquid (liquid film) 40 on the surface of the substrate W, thereby causing liquid droplets 42 to separate from the liquid film 40. The liquid droplets 42 separated from the liquid film 40 are carried by the fast gas stream, and are sucked into the gas/liquid suction nozzles 28. Relatively large liquid droplets on the surface of the substrate W are likewise carried by the fast gas stream and sucked into the gas/liquid suction nozzles 28. The gas/liquid two-phase flow, sucked into the gas/liquid suction nozzles 28, is separated into a gas and a liquid by the gas-liquid separator 34 and discharged. The suction flow rate is controlled by the blower 32 and the suction flow control valve 36.

A liquid, especially the liquid film 40, can thus be separated and removed from the surface of the substrate W by utilizing the shear stress acting on the gas-liquid interface. According to this method, therefore, there is no need to bring the suction opening of each gas/liquid suction nozzle 28 into contact with a liquid, especially the liquid film 40. Thus, the liquid film 40 having a visible level of thickness, e.g., a thickness of more than about 500 μm, can be completely removed from the surface of the substrate W. Large liquid droplets, e.g., having a diameter of more than about 500 μm can also be completely removed from the surface of the substrate W.

Positioned posterior to the gas/liquid suction nozzles 28 in the direction (X-direction) of the movement of the front surface-side nozzle 16, dry gas supply nozzles 44, each of which vertically penetrates through the body portion 20 and opens onto the substrate-facing surface 20a, are provided within the body portion 20. Each dry gas supply nozzle 44 has an inclined portion 44a which is inclined toward the direction opposite to the direction (X-direction) of the nozzle movement and extends obliquely upward from the substrate-facing surface 20a, and a vertical portion 44b which communicates with the inclined portion 44a and extends vertically. The dry gas supply nozzles 44 are each connected via a gas supply line 46 to a gas supply unit 48. A gas flow control valve 50 is interposed in the gas supply line 46.

With this construction, even when invisible minute residual liquid droplets 52, e.g., having a diameter less than 500 μm, remain on the surface of the substrate W, the rate of evaporation of the residual liquid droplets 52 is accelerated and the residual liquid droplets 52 evaporate instantaneously due to the flow of the dry gas supplied from the dry gas supply nozzles 44 to the surface of the substrate W. An invisibly thin liquid film, because of its large specific surface area, likewise evaporates instantaneously. Thus, this drying method can prevent a liquid from remaining on the surface of the substrate W, thereby preventing the formation of watermarks on the surface of the substrate W.

In this embodiment, as shown in FIG. 1, the gas/liquid suction nozzles 28, having slit-like suction openings arranged in series, and the dry gas supply nozzles 44, having slit-like supply openings arranged in series, are provided in opposing positions within the body portion 20. Thus, the entire front surface of the substrate W is divided into a plurality of zonal suction areas arranged linearly. A liquid lying in each suction area is sacked and removed into the suction opening of each gas/liquid suction nozzle 28 while liquid droplets remaining in the suction area is dried off by the dry gas supplied from the opposing dry gas supply nozzle 44. In this manner, the liquid can be removed from the entire front surface of the substrate W.

Further, in this embodiment, in order to carry out the removal of liquid from the front surface of the substrate W under optimal conditions, the suction line 30 is connected to each gas/liquid suction nozzle 28 and the gas supply line 46 is connected to each dry gas supply nozzle 44.

Located above the peripheral portion of the substrate W held by the substrate holder 14 and at anterior positions in the direction (X-direction) of the movement of the front surface-side nozzle unit 16, a number of replenishing liquid nozzles 54, for downwardly emitting a replenishing liquid toward the front surface of the substrate W, are disposed such that the replenishing liquid nozzles 54 do not interfere with the front surface-side nozzle unit 16. The replenishing liquid nozzles communicate with a replenishing liquid pipe 56. A replenishing liquid is emitted from each replenishing liquid nozzle 54 toward the front surface of the substrate W to replenish a liquid on the substrate surface. When the liquid on the surface of the substrate W is a liquid chemical, the replenishing liquid may be a liquid chemical having substantially the same components. When the liquid on the surface of the substrate W is ultrapure water for rinsing, the replenishing liquid may be ultrapure water having substantially the same level of purity. The replenished liquid emitted onto the surface of the substrate W will be taken to form the continuous film-like liquid (liquid film) 40 which easily removes from the substrate surface when it receives a shear stress applied by the fast gas stream. Thus, the liquid (liquid film) can be more effectively removed from the surface of the substrate W.

The flow rate of the replenishing liquid supplied from the replenishing liquid nozzles 54 to the surface of the substrate W is, for example, 2 to 15 L/min/m per unit length in the longitudinal direction of the front surface-side nozzle unit 16. By thus supplying the replenishing liquid from the replenishing liquid nozzles 54 to the surface of the substrate W at such a flow rate, a thickness of the continuous liquid film 40 formed on the substrate surface can be controlled, e.g., in the range of 0.5 mm to 3.5 mm.

The back surface-side nozzle unit 18, which is similar in construction to the front surface-side nozzle unit 16, includes a body portion 60 within which gas/liquid suction nozzles and dry gas supply nozzles (not shown) are provided, and support portions (not shown) coupled to both ends of the body portion 60. The each support portion is coupled to a carrier 64 of each movement mechanism 62. Similarly to the front surface-side nozzle unit 16, the gas/liquid suction nozzles and the dry gas supply nozzles, provided within the back surface-side nozzle unit 18, are connected to a suction line and a gas supply line (not shown), respectively.

To the back surface-side nozzle unit 18 is attached a support plate 66 projecting forward in the direction (X-direction) of the movement of the back surface-side nozzle unit 18. Replenishing liquid nozzles 68 for emitting a replenishing liquid, which has the same quality as the liquid on the surface of the substrate W, toward the back surface of the substrate W to replenish a liquid on the back surface are mounted on an upper surface of the support plate 66.

In operation, the substrate W is held and fixed by the substrate holder 14. While moving the front surface-side nozzle unit 16 horizontally in the movement direction (X-direction), a liquid, especially the liquid film 40, on the front surface of the substrate W is sacked into the gas/liquid suction nozzles 28 and, at the same time, a dry gas is supplied from the dry gas supply nozzles 44, thereby drying the front surface of the substrate W. Simultaneously with the drying of the front surface of the substrate W, while moving the back surface-side nozzle unit 18 horizontally in the movement direction (X-direction) in synchronization with the front surface-side nozzle unit 16 and supplying a replenishing liquid from the replenishing liquid nozzles 68 to the back surface of the substrate W, a liquid on the back surface of the substrate W is sacked into the gas/liquid suction nozzles and, at the same time, a dry gas is supplied from the dry gas supply nozzles, thereby drying the back surface of the substrate W.

By thus synchronously moving the front surface-side nozzle unit 16 and the back surface-side nozzle unit 18 horizontally in the movement direction (X-direction) to simultaneously dry the front and back surfaces of the substrate W, it becomes possible to apply almost equal suction forces to the front and back surfaces of the substrate W during the drying processing, thereby preventing deflection of the substrate W.

The back surface-side nozzle unit 18 is optional, and may be omitted.

The operation of the drying unit (substrate processing apparatus) 10 will now be described.

First, a substrate W, such as a semiconductor wafer, is held and fixed by the clampers 12 of the substrate holder 14. At this moment, the front surface-side nozzle unit 16 and the back surface-side nozzle unit 18 are each in a posterior standby position in the movement direction (X-direction). A replenishing liquid is then emitted from the replenishing liquid nozzles 54 toward the front surface of the substrate W to form a continuous film-like liquid (liquid film) 40, e.g., having a thickness of 0.5 mm to 3.5 mm, on the surface of the substrate W. Thereafter, the front surface-side nozzle unit 16 in the posterior standby position is horizontally moved parallel to the front surface of the substrate W in the movement direction (X-direction) while keeping a gap distance between the substrate W and the substrate-facing surface 20a of the body portion 20 of the front surface-side nozzle unit 16 constant.

Simultaneously with the start of the movement of the front surface-side nozzle unit 16, the blower 32 is activated to create a fast gas stream in the vicinity of the suction opening of each gas/liquid suction nozzle 28. The fast gas stream applies a shear stress to the gas-liquid interface, thereby removing the liquid film 40 from the front surface of the substrate W while breaking the liquid film 40 into liquid droplets 42. The liquid droplets 42 are carried by the fast gas stream and sucked into the gas/liquid suction nozzles 28. Relatively large liquid droplets on the surface of the substrate W, which have been separated from the liquid film 40, are also sucked into the gas/liquid suction nozzles 28. The fast gas stream has a velocity component vertical to the front surface of the substrate W. The gas/liquid two-phase flow, sucked into the gas/liquid suction nozzles 28, is separated into a gas and a liquid by the gas-liquid separator 34 and discharged. At the same time, a dry gas having a low humidity, e.g., N₂ gas, is blown from the dry gas supply nozzles 44 toward the front surface of the substrate W. Thus, even when invisibly minute residual liquid droplets 52, e.g., having a diameter of not more than about 500 μm, remain on the surface area of the substrate W which lies posterior to the gas/liquid suction nozzle 28 in the movement direction (X-direction), i.e., the surface area over which the gas/liquid suction nozzle 28 has passed, the rate of evaporation of the residual liquid droplets 52 is accelerated by the dry gas, so that the residual liquid droplets 52 is evaporated instantaneously. An invisibly thin liquid film is likewise instantaneously evaporated. The production of watermarks on the substrate surface, which would be caused by a residual liquid on the substrate surface, can thus be prevented.

In this embodiment, since the substrate is fixed by the substrate holder 14 and does not need to be rotated during drying treatment, splashing droplets from substrate edge due to centrifugal force and their rebounding towards the substrate from sidewall of chamber can thus be effectively prevented.

In synchronization with the movement of the front surface-side nozzle unit 16, the back surface-side nozzle unit 18 is moved parallel to the back surface of the substrate W in the movement direction (X-direction). Similarly to the front surface-side nozzle unit 16, simultaneously with the start of the movement of the back surface-side nozzle unit 18, the blower is activated to create a fast gas stream in the vicinity of the suction opening of each gas/liquid suction nozzle and, at the same time, a dry gas having a low humidity, e.g., N₂ gas, is blown from each dry gas supply nozzle toward the back surface of the substrate W, thereby drying the back surface of the substrate W. During the drying processing, a replenishing liquid is emitted from the replenishing liquid nozzles 68 toward the back surface of the substrate W to replenish a liquid on the back surface of the substrate W.

When the front surface-side nozzle unit 16 and the back surface-side nozzle unit 18, after moving over an entire area of the substrate W from its one edge in the movement direction (X-direction), have reached the opposite edge of the substrate W, the suction by the gas/liquid suction nozzles and the supply of the dry gas from the dry gas supply nozzles are stopped to terminate the drying processing. The front surface-side nozzle unit 16 and the back surface-side nozzle unit 18 are then returned to the standby positions.

Thus, in this embodiment, while moving the front surface-side nozzle unit 16 horizontally in the movement direction (X-direction), a liquid, especially the liquid film 40, on the front surface of the fixed substrate W is sacked into the gas/liquid suction nozzles 28 and, at the same time, a dry gas is supplied from the dry gas supply nozzles 44, thereby drying the front surface of the substrate W. When the speed of the movement of the front surface-side nozzle unit 16 is low, a liquid can be effectively removed from the substrate surface by the fast gas stream and through the evaporation of the liquid, which is promoted by the flow of the dry gas. However, when the speed of the movement of the front surface-side nozzle unit 16 is too low, in addition to the need for a longer processing time, the liquid removal effect can even decrease due to breakage of a liquid film, lying in the vicinity of the suction opening, before it is removed from the substrate surface. On the other hand, when the speed of the movement of the front surface-side nozzle unit 16 is too high, a liquid film can remain on the substrate surface without being completely removed. In view of the liquid removal effect and the processing time taken to dry the substrate W, the speed of the movement of the front surface-side nozzle unit 16 is preferably 0.01 m/s to 0.07 m/s, more preferably 0.02 m/s to 0.05 m/s. This holds true for the back surface-side nozzle unit 18.

A gap distance H between the substrate W held by the substrate holder 14 and the substrate-facing surface 20a of the body portion 20 of the front surface-side nozzle unit 16 is preferably set at 1 mm to 4 mm so that a space, e.g., having a height of about 0.5 mm or higher, is formed between the substrate-facing surface 20a and the surface of the liquid film 40, e.g., having a thickness of 0.5 mm to 3.5 mm, formed on the surface of the substrate W. The smaller the gap distance H, the larger is a shear stress which acts on the interface between a liquid film or droplets on the surface of the substrate W and a gas stream. However, in view of deformation of the substrate and the accuracy of a position adjustment mechanism, the gap distance H is preferably not less than 1 mm. On the other hand, in view of the minimum shear stress that can break a liquid film into liquid droplets, the gap distance H is preferably not more than 4 mm. The gap distance H is more preferably 1.5 mm to 2.5 mm. Similarly, a gap distance between the substrate W held by the substrate holder 14 and the back surface-side nozzle unit 18 is preferably 1 mm to 4 mm, more preferably 1.5 mm to 2.5 mm.

The suction flow rate is preferably controlled by the blower 32 and the suction flow control valve 36 so that a gas flows along the surface of the substrate W in the gap between the substrate W and the substrate-facing surface 20a of the body portion 20 at an average flow speed (suction flow speed) of 60 m/s to 140 m/s, and is sucked into the gas/liquid suction nozzles 28. By thus allowing a gas to flow along the substrate surface at an average flow speed of 60 m/s to 140 m/s and to be sucked into the gas/liquid suction nozzles 28, a shear stress can be obtained which is sufficient to remove the liquid film 40 from the surface of the substrate W and break the liquid film 40 into liquid droplets that will be sucked into the gas/liquid suction nozzles 28. The suction flow rate is more preferably controlled so that a gas flows along the surface of the substrate W at an average flow speed (suction flow speed) of 65 m/s to 95 m/s, and is sucked into the gas/liquid suction nozzles 28. This holds true for the back surface-side nozzle unit 18.

It is preferred that the dry gas be an inert gas, such as N₂ gas, and the relative humidity of the dry gas be not more than the relative humidity of the atmosphere. The use of a dry gas, having a relative humidity which is not more than the relative humidity of the atmosphere, can more effectively evaporate the residual liquid droplets 52 or the liquid film remaining on the surface of the substrate W. Taking account of the production cost of an inert gas having a low relative humidity and the evaporation promoting effect, it is preferred to use a dry gas having such a relative humidity as to make the relative humidity of the atmosphere 1% to 40%, more preferably 5% to 10% in the vicinity of the dry gas supply opening.

A description will now be given of an experiment in which a 300-mm wafer whose front surface is wet with a liquid was dried by using the front surface-side nozzle unit 16 (hereinafter simply referred to as nozzle unit) of the drying unit 10 shown in FIGS. 1 and 3. A blanket wafer having a SiOC:H low-k surface film with a dielectric constant of about 2.8, formed by CVD, was used as the 300-mm wafer and ultrapure water was used as the liquid. The wafer surface has such hydrophobicity that the contact angle of an ultrapure water droplet is 50° to 100°. The experiment was conducted in a clean room environment in which the temperature of the atmosphere was controlled at 20° C. and the relative humidity of the atmosphere was controlled at 50%.

Using a defect inspection device Surfscan SP1 (KLA-Tencor Corp.), the number of defects having a size of not less than 160 nm, present in the surface area of the wafer before processing over which the nozzle unit will pass, was measured and recorded. The same measurement was also carried out for the wafer after processing (wetting and drying the wafer). The number of defects (hereinafter referred to as “Adder”) in the wafer before and after processing was used as an evaluation index of watermarks. As integrated circuits become finer, the requirement for Adder density (Adder per unit area) is becoming increasingly stricter and, at present, a spec of about 0.05/cm² to 0.5/cm² is generally required. The target of this experiment is to achieve such a requirement. In this experiment, a spec value was taken as a reference value, and a watermark evaluation value (hereinafter simply referred to as evaluation value) was determined by making a measured Adder density dimensionless based on the reference value: For example, when the spec value of a particular product is 0.1/cm², the evaluation value can be determined by dividing a measured Adder density by 0.1. Thus, the spec requirement is met when the evaluation value is not more than 1.

Parameters that affect the evaluation value include the suction flow speed, the flow rate of the dry gas supplied, the relative humidity of the dry gas, the gap distance between a substrate and the substrate-facing surface of the nozzle unit, and the speed of the movement of the nozzle unit.

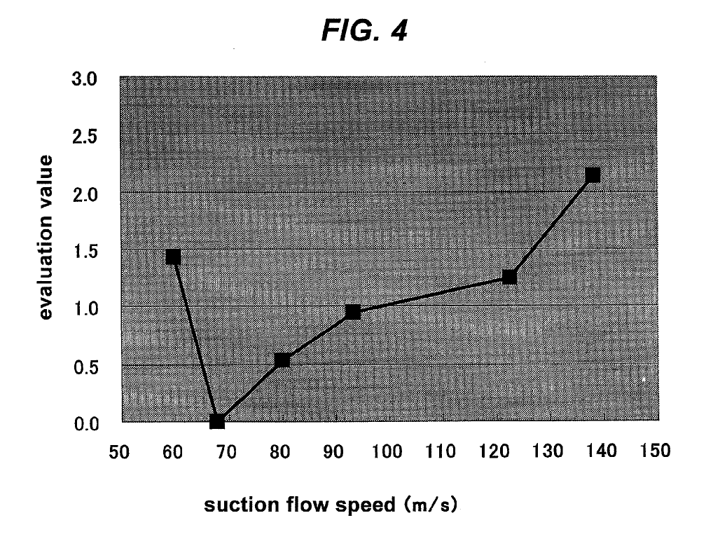

First, the influence of the suction flow speed on the evaluation value was determined by adjusting the suction flow rate so that the average flow speed (suction flow speed) of a gas flowing in the gap between the wafer and the substrate-facing surface of the nozzle unit varies in the range of 60 m/s to 140 m/s. The gap distance between the wafer and the substrate-facing surface of the nozzle unit was set at 2 mm. N₂ gas, having such a relative humidity as to make the relative humidity of the atmosphere about 40% in the vicinity of the dry gas supply opening, was used as a dry gas. The flow rate of N₂ gas supplied was set at 100 L/min/m per unit length in the longitudinal direction of the nozzle unit, and the speed of the movement of the nozzle unit was set at 0.03 m/s. FIG. 4 shows the relationship between the evaluation value and the suction flow speed. In the following description, the flow rate of a dry gas, such as N₂ gas, is per unit length in the longitudinal direction of the nozzle unit.

As can be seen from FIG. 4, while the evaluation value is as high as 1.5 at a suction flow speed of 60 m/s, the evaluation value decreases to 0, the lowest value, as the suction flow speed is increased to 68 m/s. The “0” evaluation value indicates complete prevention of the formation of watermarks. The evaluation value gradually increases as the suction flow speed is further increased. Provided that the evaluation value range of 0 to 1 is an allowable range for processing, the suction flow speed needs to be set within the range of 63 m/s to 95 m/s, with about 68 m/s being optimal, as can be also seen from FIG. 4.

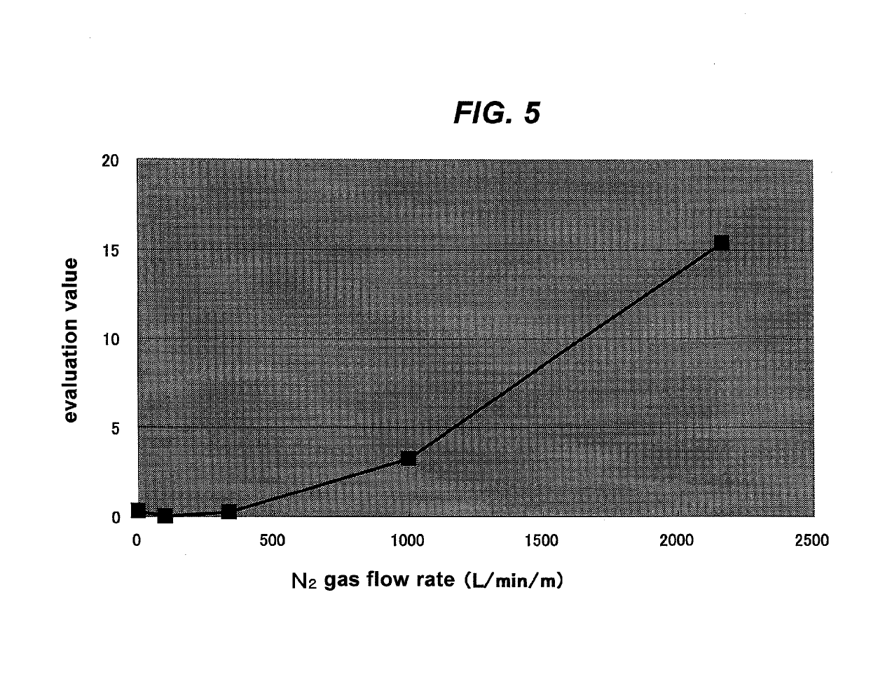

The influence of the flow rate of N₂ gas (dry gas) supplied on the evaluation value was determined by using, as a dry gas, N₂ gas having such a relative humidity as to make the relative humidity of the atmosphere about 40% in the vicinity of the dry gas supply opening, and varying the N₂ gas flow rate in the range of 0 to 2000 L/min/m. The suction flow speed was set at 68 m/s, the gap distance between the wafer and the substrate-facing surface of the nozzle unit was set at 2 mm, and the speed of movement of the nozzle unit was set at 0.03 m/s. FIG. 5 shows the relationship between the evaluation value and the flow rate of N₂ gas supplied.

As can be seen from FIG. 5, the evaluation value is within the allowable range of 0 to 1 when the N₂ gas flow rate is not more than 500 L/min/m, whereas the evaluation value significantly increases with increase in the N₂ gas flow rate in the range over 500 L/min/m, indicating a significant increase in the number of watermarks. This is considered to be due to the fact that as the flow speed of the dry gas (N₂ gas) in the vicinity of the supply opening of the dry gas supply nozzle approaches the suction flow speed, the flow of the dry gas (N₂ gas) comes to greatly affect the flow of a gas between the wafer and the substrate-facing surface of the nozzle unit and disturb the gas-liquid interface between the fast gas stream and the edge of a liquid film on the wafer surface, which will promote the formation of watermarks.

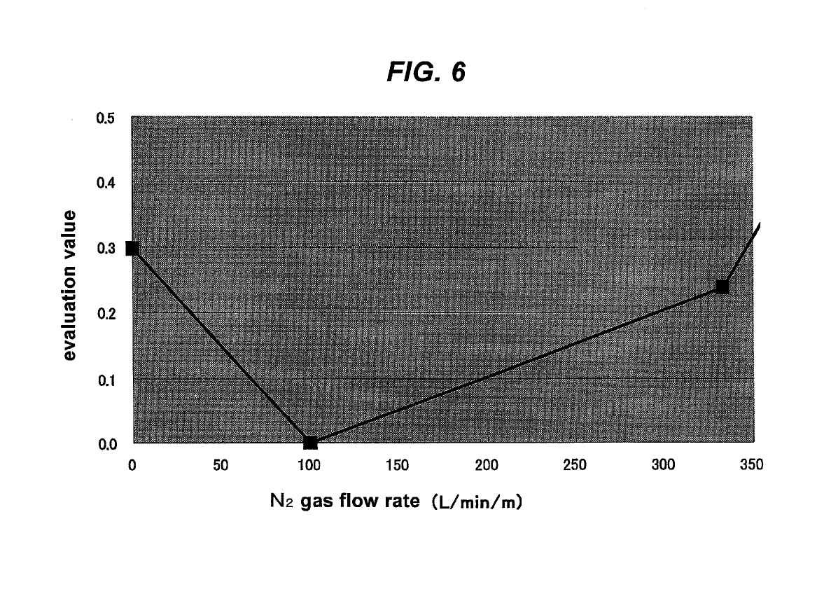

FIG. 6 shows the relationship between the evaluation value and the flow rate of N₂ gas supplied in a low N₂ gas flow rate range. It is apparent from FIG. 6 that the evaluation value is less than 1 in the low N₂ gas flow rate range of 0 to 350 L/min/m, and that compared to the case of no supply of N₂ gas, the effect of preventing watermarks can be increased by blowing N₂ gas at a low flow rate from the supply opening of the dry gas supply nozzle. This is considered to be due to the fact that when N₂ gas is supplied in an amount which does not affect the flow of a gas between the wafer and the substrate-facing surface of the nozzle unit, the N₂ gas can adjust the humidity of the atmosphere in the gap between the wafer and the substrate-facing surface of the nozzle unit, thereby accelerating the rate of evaporation of minute liquid droplets remaining on the wafer surface.

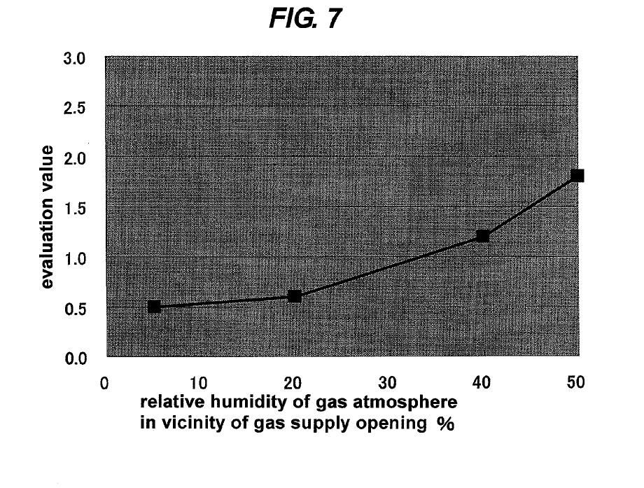

The influence of the relative humidity of the gas atmosphere in the vicinity of the gas supply opening on the evaluation value was determined by using dry air as a dry gas and varying the relative humidity in the range of 5% to 50%. The flow rate of dry air supplied was set at 100 L/min/m, the suction flow speed was set at 60 m/s, the gap distance between the wafer and the substrate-facing surface of the nozzle unit was set at 2 mm, and the speed of movement of the nozzle unit was set at 0.03 m/s. FIG. 7 shows the relationship between the evaluation value and the relative humidity of the gas atmosphere in the vicinity of the gas supply opening.

As can be seen from FIG. 7, the evaluation value is more than 1, i.e., out of the allowable range, when the relative humidity of the gas atmosphere in the vicinity of the gas supply opening exceeds about 34%, whereas the evaluation value is not more than 1 when the relative humidity of the gas atmosphere in the vicinity of the gas supply opening is not more than about 34%, indicating decreased watermarks. This is considered to be due to the fact that because of mixing of the dry gas, supplied to the gap between the wafer and the substrate-facing surface of the nozzle unit, with a fast gas stream caused by suction, the relative humidity of the atmosphere in the gap is lowered, which promotes the evaporation of minute liquid droplets remaining on the wafer surface.

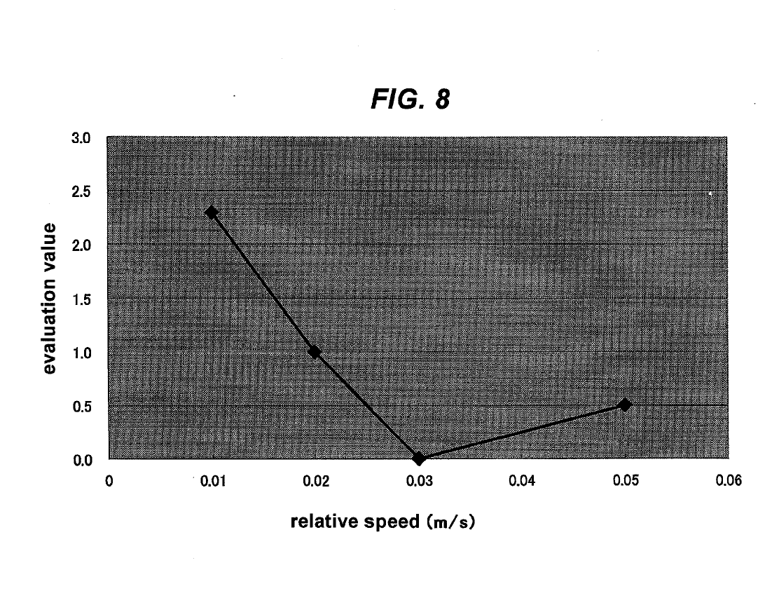

The influence of the relative speed between the nozzle unit and the wafer on the evaluation value was determined by varying the speed of the movement of the nozzle unit in the range of 0.01 m/s to 0.05 m/s while keeping the wafer stationary. N₂ gas, having such a relative humidity as to make the relative humidity of the atmosphere about 40% in the vicinity of the dry gas supply opening, was used as a dry gas and the flow rate of N₂ gas supplied was set at 100 L/min/m. The suction flow speed was set at 60 m/s, the gap distance between the wafer and the substrate-facing surface of the nozzle unit was set at 2 mm. FIG. 8 shows the relationship between the evaluation value and the relative speed.

As can be seen from FIG. 8, the evaluation value is within the allowable range of 0 to 1 when the relative speed between the nozzle unit and the wafer is not less than 0.02 m/s, and especially the evaluation value is lowest when the relative speed between the nozzle unit and the wafer is about 0.03 m/s. At such relative speed, it takes only ten seconds to dry a 300-mm wafer.

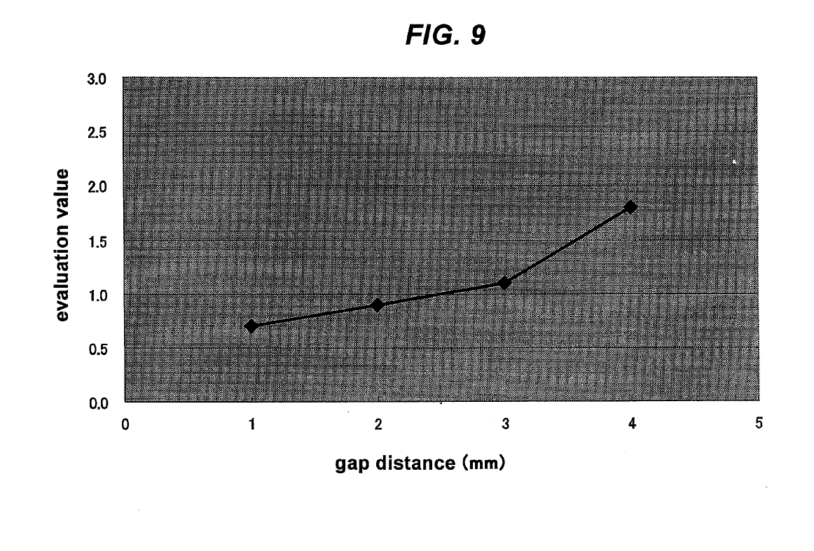

The influence of the gap distance between the wafer and the substrate-facing surface of the nozzle unit on the evaluation value was determined by varying the gap distance in the range of 1 mm to 4 mm. N₂ gas, having such a relative humidity as to make the relative humidity of the atmosphere about 40% in the vicinity of the dry gas supply opening, was used as a dry gas and the flow rate of N₂ gas supplied was set at 100 L/min/m. The suction flow speed was set at 60 m/s, and the speed of movement of the nozzle unit was set at 0.03 m/s. FIG. 9 shows the relationship between the evaluation value and the gap distance.

As can be seen from FIG. 9, at the set suction flow speed (not the optimal flow speed), the evaluation value is not less than 1 when the gap distance is not less than 2.5 mm. At a gap distance of 5 mm, a liquid film was not completely sucked and a visible liquid film remained on the wafer surface, and therefore the defect measurement was impossible.

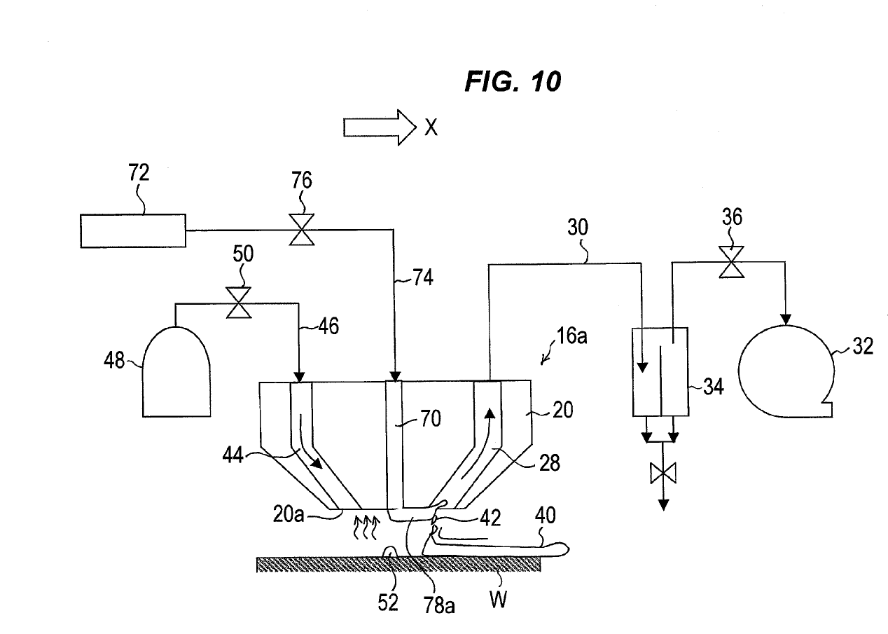

FIG. 10 shows a front surface-side nozzle unit 16a of a drying unit according to another embodiment of the present invention. The front surface-side nozzle unit 16a differs from the front surface-side nozzle unit 16 shown in FIGS. 1 through 3 in that liquid supply nozzles 70, each of which vertically extending and penetrating through the body portion 20 and opening onto the substrate-facing surface 20a of the body portion 20, are provided within the body portion 20 in a position between the gas/liquid suction nozzles 28 and the dry gas supply nozzles 44, i.e., posterior to the gas/liquid suction nozzles 28 and anterior to the dry gas supply nozzles 44 in the movement direction (X-direction) of the front surface-side nozzle unit 16a, and that each liquid supply nozzle 70 is connected via a liquid supply line 74 to a liquid supply unit 72, and a liquid flow control valve 76 is interposed in the liquid supply line 74. A liquid, such as ultrapure water, is supplied from the liquid supply nozzles 70 toward a front surface of a substrate W. The flow rate of the liquid supplied is controlled by the liquid supply unit 72 and the liquid flow control valve 76.

According to this embodiment, when drying the surface of the substrate W by sucking a liquid, especially a liquid film 40, into the gas/liquid suction nozzles 28 and, at the same, supplying a dry gas from the dry gas supply nozzles 44 while moving the front surface-side nozzle unit 16a horizontally in the X-direction, a liquid 78a is supplied from the liquid supply nozzles 70 toward the substrate W so that, as shown in FIG. 10, the liquid 78a supplied flows on that area of the substrate-facing surface 20a of the body portion 20 which lies between the supply openings of the liquid supply nozzles 70 and the suction openings of the gas/liquid suction nozzles 28. A liquid that has spattered onto and remains on that area of the substrate-facing surface 20a which lies between the supply openings of the liquid supply nozzles 70 and the suction openings of the gas/liquid suction nozzles 28, can be washed away and removed by the liquid 78a supplied from the liquid supply nozzles 70, thereby preventing the liquid remaining on the area from re-attaching to the surface of the substrate W.

An experiment was conducted in which drying of a front surface of a substrate W was carried out while supplying a liquid from the liquid supply nozzles 70 at a flow rate of 12 L/min/m under the following conditions: the suction flow speed in the gap between the substrate W and the substrate-facing surface 20a of the front surface-side nozzle unit 16a, 16 m/s; the flow rate of the dry gas supplied, 100 L/min/m; the gap distance between the substrate W and the substrate-facing surface 20a of the front surface-side nozzle unit 16a, 1 mm; and the speed of movement of the front surface-side nozzle unit 16a, 0.01 m/s. As a result, no visible residual liquid was observed on the front surface of the substrate W.

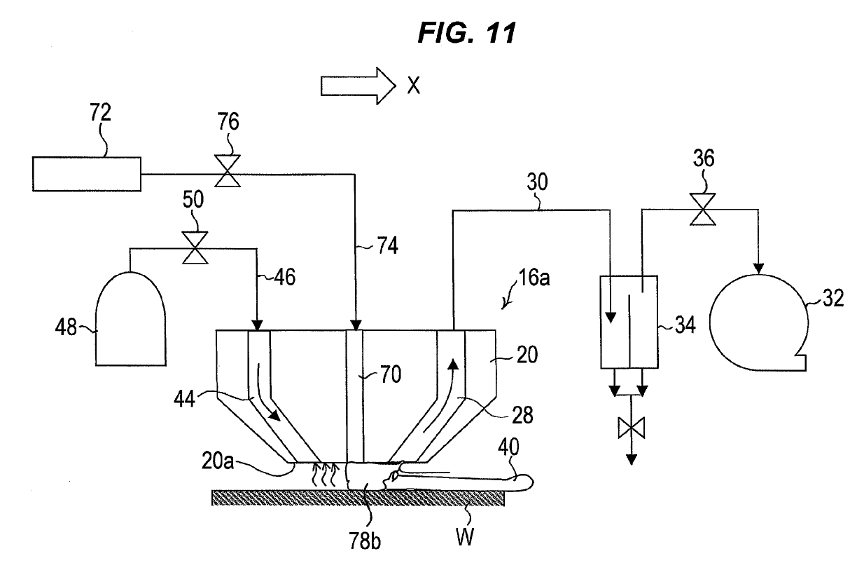

As shown in FIG. 11, it is also possible to allow a liquid 78b, supplied from the liquid supply nozzles 70 toward the substrate W, to reach a front surface of the substrate W and flow on that area of the substrate-facing surface 20a of the body portion 20 which lies between the supply openings of the liquid supply nozzles 70 and the suction openings of the gas/liquid suction nozzles 28. According to this manner, in addition to a liquid that has spattered onto and remains on that area of the substrate-facing surface 20a which lies between the supply openings of the liquid supply nozzles 70 and the suction openings of the gas/liquid suction nozzles 28, liquid droplets remaining on the area, facing that area of the substrate-facing surface 20a, of the front surface of the substrate W, can also be washed away and removed by the liquid 78b supplied from the liquid supply nozzles 70.

An experiment was conducted in which drying of a front surface of a substrate W was carried out while supplying a liquid from the liquid supply nozzles 70 at a flow rate of 6 L/min/m under the following conditions: the suction flow speed in the gap between the substrate W and the substrate-facing surface 20a of the front surface-side nozzle unit 16a, 90 m/s; the flow rate of the dry gas supplied, 100 L/min/m; the gap distance between the substrate W and the substrate-facing surface 20a of the front surface-side nozzle unit 16a, 2 mm; and the speed of movement of the front surface-side nozzle unit 16a, 0.03 m/s. As a result, it was found that the number of defects in the substrate surface can be decreased to about 36% of the number of defects as measured when the front surface of the substrate W was dried without supplying the liquid from the liquid supply nozzles 70.

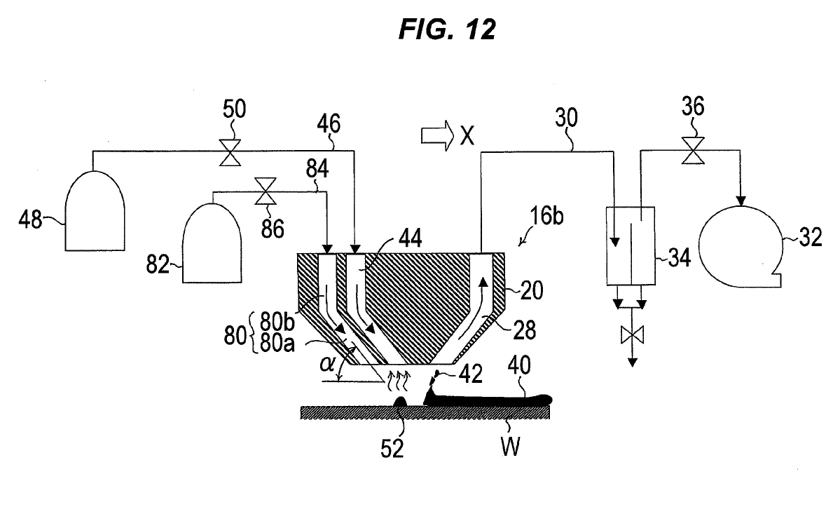

FIG. 12 shows a front surface-side nozzle unit 16b of a drying unit according to yet another embodiment of the present invention. The front surface-side nozzle unit 16b differs from the front surface-side nozzle unit 16 shown in FIGS. 1 through 3 in that organic solvent supply nozzles 80, each of which vertically extending and penetrating through the body portion 20 and opening onto the substrate-facing surface 20a of the body portion 20, are provided within the body portion 20 in a position posterior to the dry gas supply nozzles 44 in the movement direction (X-direction) of the front surface-side nozzle unit 16b, and that each organic solvent supply nozzle 80 is connected via an organic solvent supply line 84 to an organic solvent supply unit 82, and an organic solvent flow control valve 86 is interposed in the organic solvent supply line 84. A water-soluble organic solvent, in a vapor or liquid form, is supplied from the organic solvent supply nozzles 80 toward a front surface of a substrate W. The flow rate of the water-soluble organic solvent supplied is controlled by the organic solvent supply unit 82 and the organic solvent flow control valve 86.

Though in this embodiment the organic solvent supply nozzles 80 are provided in a position posterior to the dry gas supply nozzles 44 in the movement direction (X-direction) of the front surface-side nozzle unit 16b, it is also possible to provide the organic solvent supply nozzles 80 in a position between the gas/liquid suction nozzles 28 and the dry gas supply nozzles 44 in the movement direction (X-direction) of the front surface-side nozzle unit 16b.

Each organic solvent supply nozzle 80 has an inclined portion 80a which is inclined toward the direction opposite to the direction (X-direction) of the movement of the nozzle unit 16b and extends obliquely upward from the substrate-facing surface 20a, and a vertical portion 80b which communicates with the inclined portion 80a and extends vertically. The inclination angle α of the inclined portion 80a of the organic solvent supply nozzle 80 to the surface of the substrate W is set, e.g., at 45° to 90°.

A water-soluble organic solvent, in a vapor or liquid form, is thus supplied toward the front surface of the substrate W from the organic solvent supply nozzles 80 at a position posterior to the dry gas supply nozzles 44 in the direction (X-direction) of the movement of the nozzle unit 16b relative to the substrate W. Even when minute liquid droplets remain on the front surface of the substrate W, the water-soluble organic solvent supplied can be dissolved in the minute liquid droplets to accelerate the rate of evaporation of the minute liquid droplets. This makes it possible to dry the substrate W while preventing the formation of watermarks. The water-soluble organic solvent can be used only in such an amount as to dissolve it in the minute liquid droplets remaining on the surface of the substrate W. Thus, the amount of the water-soluble organic solvent used can be significantly reduced compared to the conventional method.

It has been confirmed that the rate of evaporation of liquid droplets, remaining on the surface of the substrate W, can be increased by setting the inclination angle α of the inclined portion 80a of the organic solvent supply nozzle 80 to the surface of the substrate W at, e.g., 45° to 90°.

For the organic solvent supply unit 82, the organic solvent supply line 84, etc. are used a container, a pipe, etc. made of a material inert to an organic solvent, such as stainless steel, hard glass, fluororesin, etc. An organic solvent vapor can be generated by introducing a pipe into a container, constituting the organic solvent supply unit 82, with a front end of the pipe immersed in an organic solvent in the container, and passing an inert gas through the pipe. The generation of the organic solvent vapor can be promoted by attaching a bubble generator, such as a bubbler, having fine holes to the front end of the pipe. The organic solvent vapor generated in the organic solvent supply unit 82 is carried to a surface of a substrate by the inert gas flowing in the container and through a pipe.

The organic solvent may be used either in the liquid state or in the vapor state. The vapor pressure of an organic solvent increases exponentially with increase in the temperature. When controlling the vapor concentration, therefore, it is desirable to keep the container, the pipe, etc. at a constant temperature, e.g., by means of a constant-temperature unit.

An organic solvent, which is miscible with a liquid on a substrate, such as pure water, and has a higher evaporation rate than the liquid, can be used as the water-soluble organic solvent capable of quickly evaporating and drying off liquid droplets on the substrate. The solubility parameter (SP value) and the vapor pressure or boiling point of an organic solvent can be used as an index of its miscibility with the liquid, such as ultrapure water, and as an index of its evaporation rate, respectively. The solubility parameter provides an indication of solubility between two or more liquids. As is empirically known, the smaller the difference between the SP values of components of a solution, the larger is the solubility between the components.

With reference to solubility in water, the solubility parameter of water is 23.43 (cal/cm³)^{1/2}. A nearer solubility parameter to that value indicates a higher solubility in water (miscibility or compatibility with water). For example, the SP values of exemplary water-soluble monohydric alcohols, in order of increasing number of carbon atoms, are as follows: methanol (13.77), ethanol (12.57), 1-propanol (11.84), 2-propanol (11.58), and 1-butanol (11.32). As is known for monohydric alcohols, the larger the number of carbon atoms, i.e., the larger the number of hydrophobic alkyl groups, the poorer is the solubility in water. For example, n-hexanol, which is insoluble in water, has 6 carbon atoms and has an SP value of 10.7 that is largely different from the SP value 23.43 of water. Thus, by knowing the SP values of organic solvents, water-soluble organic solvents to be appropriately used can be selected. Such usable water-soluble organic solvents include oxygen-containing compounds such as the above-described alcohols, nitrogen-containing compounds and sulfur-containing compounds.

Examples of oxygen-containing compounds include monohydric alcohols, such as methanol, ethanol, propanol and furfuryl alcohol; polyhydric alcohols, such as ethylene glycol, propylene glycol, trimethylene glycol, chloropropane diol, butane diol, pentane diol and hexylene glycol; derivatives of polyhydric alcohols, such as ethylene glycol diglycidyl ether, ethylene glycol dimethyl ether, ethylene glycol monoacetate, ethylene glycol monomethyl ether, ethylene glycol monoethyl ether and ethylene glycol monobutyl ether; ethers, such as diethyl ether, dipropyl ether, dioxane, tetrahydropyran and tetrahydrofuran; acetals; ketones, such as acetone, diacetone alcohol and methyl ethyl ketone; aldehydes, such as acetaldehyde; and esters, such as butyrolactone.

Examples of nitrogen-containing compounds include amines, such as methylamine, dimethylamine, ethylamine, propylamine, allylamine, butylamine, diethylamine, amylamine, cyclohexylamine, 2-ethylhexylamine, propanolamine, N-ethylethanolamine, N-butylethanolamine and triethanolamine; diamines, such as ethylene diamine, propylene diamine and N,N,N′,N′-tetramethylethylene diamine; and tertamethylammonium oxide.

Examples of sulfur-containing compounds include dimethyl sulfoxide and sulfolane.

An organic solvent to be used, besides the necessity of being soluble in water as described above, needs to possess volatility which promotes evaporation of a liquid such as ultrapure water. The vapor pressure of an organic solvent can suitably be used as an index of such volatility of the organic solvent. If the vapor pressure of an organic solvent is higher than the vapor pressure of water, 2.3 kPa (20° C.), then the organic solvent can promote evaporation of water. The vapor pressures at 20° C. of some exemplary monohydric alcohols are as follows: methanol (12.3 kPa), ethanol (5.9 kPa), and 2-propanol (4.4 kPa). These alcohols can therefore promote evaporation of water.

Examples of organic solvents which meet the solubility parameter and vapor pressure requirements include methanol, ethanol and 2-propanol which are monohydric alcohols.

Not alone a single organic solvent, but a mixture of two or more organic solvents may be used. When a mixture of organic solvents is used, it suffices if one of them is a water-soluble organic solvent. The other organic solvent(s), if not soluble in water, is preferably soluble in the water-soluble organic solvent. An organic solvent having a high vapor pressure, such as a hydrofluoroether (HFE), may preferably be used as the other organic solvent.

When a flammable water-soluble organic solvent is used, it is very important to control its vapor concentration. For example, isopropyl alcohol (IPA), which is a flammable water-soluble organic solvent, is preferably used. The lower flash point of IPA is about 12° C., and the saturated vapor concentration at that temperature, determined from the saturated vapor pressure-temperature relation, is about 2.2%. Therefore, when IPA is used, it is preferably used at a vapor concentration of less than 2.2% for safety reasons.

When liquid droplets evaporate from a substrate surface, the substrate will be cooled by the latent heat of evaporation. Therefore, dew condensation of water vapor can occur on the substrate surface. Therefore, when there is a fear of such dew condensation, it is preferred to use a warmed inert gas or to provide a means for warming a substrate so that the temperature of a substrate will not fall below the dew point.

In order to quickly evaporate liquid droplets on a substrate surface with an organic solvent vapor to thereby dry the substrate, it is necessary to efficiently supply the organic solvent vapor to the liquid droplets on the substrate. If the organic solvent vapor contacts entire surfaces of the liquid droplets, the rate of dissolution of the organic solvent in the liquid droplets will be high, and therefore the liquid droplets will evaporate quickly. An experiment was conducted in which the angle between a substrate surface and the direction of an organic solvent vapor emitted from the organic solvent supply opening, i.e., the inclination angle α of the inclined portion 80a of the organic solvent supply nozzle 80 to the substrate surface, shown in FIG. 12, was varied in the range of 10° to 90° in carrying out drying of a liquid droplet on the substrate surface to determine the relationship between the angle and the evaporation rate of the liquid droplet.

In particular, a Si substrate (sample) having a surface film of low-k material (BD1, film thickness 10,000 Angstroms) was prepared. 0.02 ml of an ultrapure water droplet was dropped from a pipette onto the sample (Si substrate) placed on a precision balance, and an IPA vapor was emitted toward the water droplet. The drying rate of the water droplet was determined from change in the weight of the sample. The IPA vapor was generated by introducing nitrogen gas through a porous glass body, provided at a front end of a PFA tube, into a liquid IPA filled in a SUS container and bubbling the nitrogen gas in the liquid IPA. The IPA vapor thus generated was carried to the sample. The flow rate of nitrogen gas was controlled at 2 L/min, and the temperature of the IPA vapor in the SUS container was controlled at about 23° C. The IPA concentration in the vicinity of the supply opening, measured with a gas detector tube, was 2.1% that is less than the saturated vapor concentration at the lower flash point of IPA.

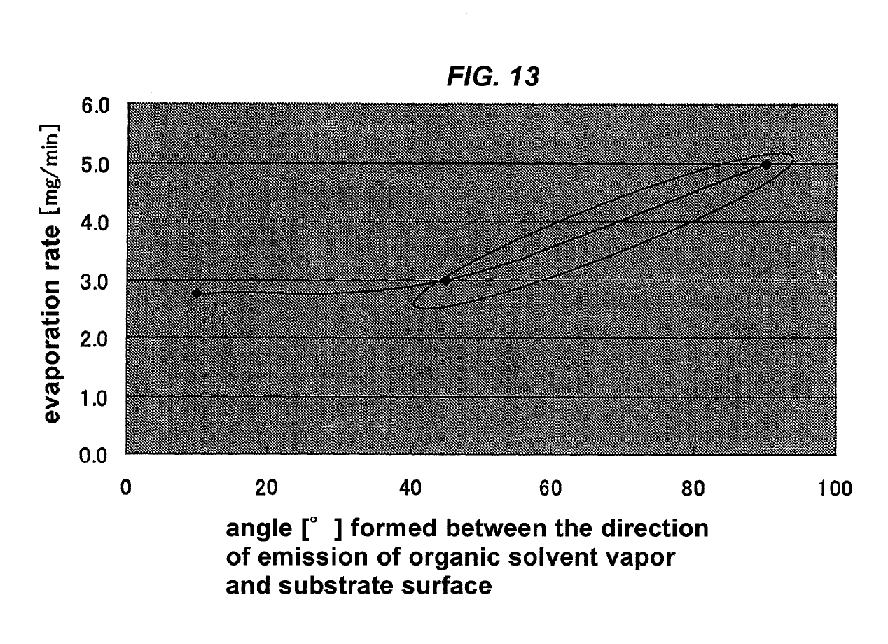

The results are shown in FIG. 13. As can be seen from FIG. 13, the evaporation rate of water droplet increases significantly as the angle between the substrate surface and the direction of the IPA vapor emitted from the organic solvent supply opening of the drying device, i.e., the inclination angle α of the inclined portion 80a of the organic solvent supply nozzle 80 to the substrate surface, shown in FIG. 12, increases in the range of not less than 45°. Thus, the effect of IPA on acceleration of the evaporation rate increases with increase in the angle in the range of 45° to 90°. No watermark was observed on the substrate surface after drying.

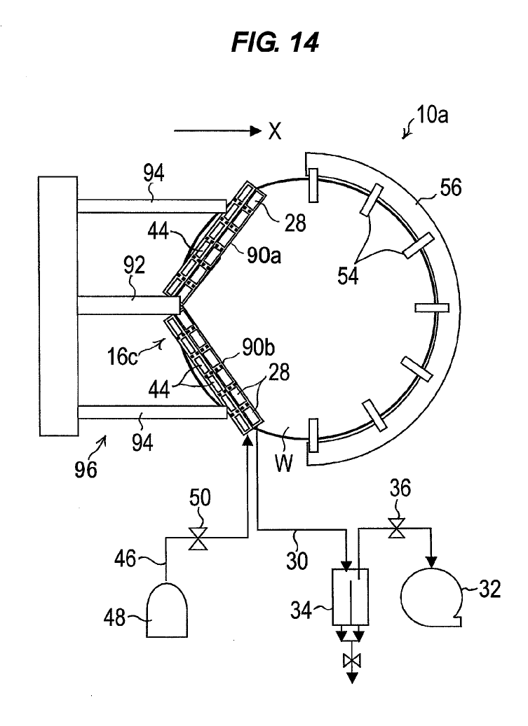

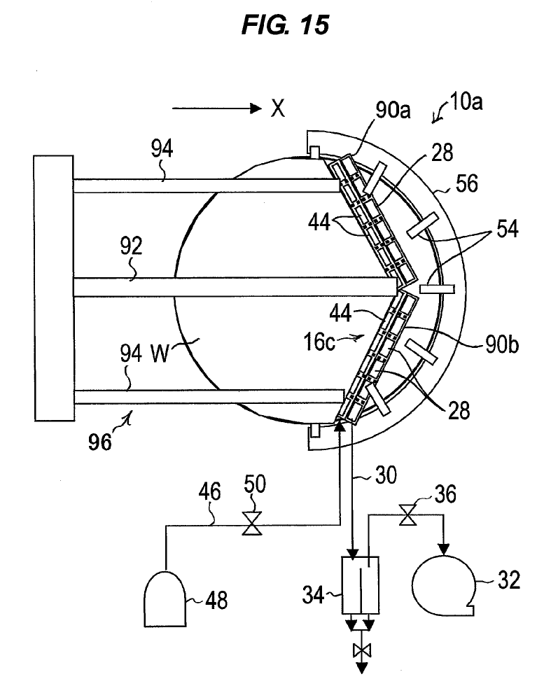

FIGS. 14 and 15 show a substrate processing apparatus 10a, configured as a drying unit, according to yet another embodiment of the present invention. The drying unit (substrate processing apparatus) 10a of this embodiment differs from the drying unit 10 shown in FIGS. 1 through 3 in the following respects: A front surface-side nozzle unit 16c is comprised of a pair of body portions 90a, 90b, coupled to each other linearly and each interiorly having gas/liquid suction nozzles 28 and dry gas supply nozzles 44. A movement mechanism 96 for moving the front-side nozzle unit 16c in the movement direction (X-direction) is comprised of a central extensible member 92 which is horizontally extensible and coupled to the body portions 90a, 90b at their joint-side ends, and a pair of side extensible members 94 which are horizontally extensible and coupled to the other ends of the body portions 90a, 90b, respectively. The speed of movement (extension) of the central extensible member 92 is set higher than the speed of movement (extension) of the side extensible members 94. Aback surface-side nozzle unit is not provided in this embodiment.

In operation, while moving the front surface-side nozzle unit 16c horizontally in the X-direction by extending the central extensible member 92 and the side extensible members 94 of the movement mechanism 96, a liquid on a surface of a substrate W is sacked into the gas/liquid suction nozzles 28 and, at the same time, a dry gas is supplied from the dry gas supply nozzles 44, thereby drying the surface of the substrate W. By moving (extending) the central extensible member 92 at a higher speed than the side extensible members 94, the entire surface of the substrate W can be dried at a more uniform rate.

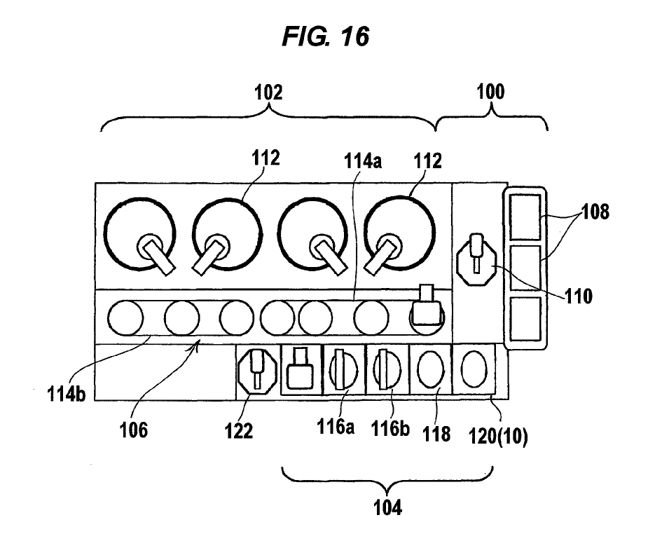

FIG. 16 shows a polishing apparatus incorporating a drying unit (substrate processing apparatus) according to the present invention. As shown in FIG. 16, the polishing apparatus comprises a loading/unloading section 100 for carrying in and out a substrate, a polishing section 102 for polishing and flattening the surface of the substrate, a cleaning section 104 for cleaning the substrate after polishing, and a substrate transport section 106 for transporting the substrate. The loading/unloading section 100 includes a front loading section 108 mounted with a plurality of (e.g., three as shown) substrate cassettes for storing substrates, such as semiconductor wafers, and a first transport robot 110.

In this embodiment, the polishing section 102 includes four polishing units 112. The substrate transport section 106 is comprised of a first linear transporter 114a and a second linear transporter 114b each for transporting a substrate between two adjacent polishing units 112. The cleaning section 104 has two cleaning units 116a, 116b each for performing rough cleaning, e.g., with a roll brush, a cleaning unit 118 for performing finish cleaning, and a drying unit 120. The polishing apparatus also includes a second transport robot 122 positioned between the first linear transporter 114a, the second linear transporter 114b and the cleaning section 104.

In this embodiment, the above-described drying unit 10 shown in FIGS. 1 through 3 is used as the drying unit 120, and a substrate after polishing and cleaning is dried in the drying unit 120 (10). It is possible to use the drying unit 10a shown in FIGS. 14 and 15 instead of the drying unit 10 shown in FIGS. 1 through 3.

In operation of the polishing apparatus, a substrate is taken by the first transport robot 110 out of one of the substrate cassettes mounted in the front loading section 108, and the substrate is transported, via the first linear transporter 114a or via the first linear transporter 114a and the second linear transporter 114b, to one of the polishing units 112 of the polishing section 102, where the substrate is polished. The substrate after polishing is transported by the second transport robot 122 to the cleaning section 104, where the substrate is sequentially cleaned in the cleaning units 116a, 116b and the cleaning unit 118 and dried in the drying unit 120. Thereafter, the substrate is returned by the first transport robot 110 to the substrate cassette mounted in the front loading section 108.

While the present invention has been described with reference to preferred embodiments, it is understood that the present invention is not limited to the embodiments, but is capable of various modifications within the inventive concept.

What is claimed is:

1. A substrate processing method for drying a substrate surface which is wet with a liquid, comprising:
removing the liquid from the substrate surface and sucking the liquid together with its surrounding gas into a gas/liquid suction nozzle, disposed opposite the substrate surface, while relatively moving the gas/liquid suction nozzle and the substrate parallel to each other; and
blowing a dry gas from a dry gas supply nozzle, disposed opposite the substrate surface, toward that area of the substrate surface from which the liquid has been removed while relatively moving the dry gas supply nozzle and the substrate parallel to each other.

2. The substrate processing method according to claim 1, wherein the gas/liquid suction nozzle and the dry gas supply nozzle are moved integrally relative to the substrate, with the gas/liquid suction nozzle being positioned anterior to the dry gas supply nozzle in the direction of their movement relative to the substrate.

3. The substrate processing method according to claim 2, wherein the speed of the movement of the gas/liquid suction nozzle and the dry gas supply nozzle relative to the substrate is 0.01 m/s to 0.07 m/s.

4. The substrate processing method according to claim 1, wherein a liquid is supplied toward the substrate surface from a liquid supply nozzle at a position posterior to the gas/liquid suction nozzle and anterior to the dry gas supply nozzle in the direction of their movement relative to the substrate.

5. The substrate processing method according to claim 4, wherein the gas/liquid suction nozzle, the dry gas supply nozzle and the liquid supply nozzle are moved integrally relative to the substrate, with the gas/liquid suction nozzle being positioned anterior to the dry gas supply nozzle and the liquid supply nozzle being positioned between the gas/liquid suction nozzle and the dry gas supply nozzle in the direction of their movement relative to the substrate.

6. The substrate processing method according to claim 5, wherein the speed of the movement of the gas/liquid suction nozzle, the dry gas supply nozzle and the liquid supply nozzle relative to the substrate is 0.01 m/s to 0.07 m/s.

7. The substrate processing method according to claim 1, wherein a water-soluble organic solvent is supplied toward the substrate surface from an organic solvent supply nozzle at a position posterior to the gas/liquid suction nozzle in the direction of its movement relative to the substrate.

8. The substrate processing method according to claim 7, wherein the gas/liquid suction nozzle, the dry gas supply nozzle and the organic solvent supply nozzle are moved integrally relative to the substrate, with the gas/liquid suction nozzle being positioned anterior to the dry gas supply nozzle and the organic solvent supply nozzle, and one of the dry gas supply nozzle and the organic solvent supply nozzle being positioned anterior to the other in the direction of their movement relative to the substrate.

9. The substrate processing method according to claim 8, wherein the speed of the movement of the gas/liquid suction nozzle, the dry gas supply nozzle and the organic solvent supply nozzle relative to the substrate is 0.01 m/s to 0.07 m/s.

10. The substrate processing method according to claim 7, wherein the water-soluble organic solvent is isopropyl alcohol.

11. The substrate processing method according to claim 10, wherein the vapor concentration of the isopropyl alcohol is less than 2.2%.

12. The substrate processing method according to claim 1, wherein a gap distance between a suction opening of the gas/liquid suction nozzle and the substrate surface is 1 mm to 4 mm.

13. The substrate processing method according to claim 1, wherein the suction flow rate is controlled so that a gas flows along the substrate surface at an average flow speed of 60 m/s to 140 m/s, and is sucked into the gas/liquid suction nozzle.

14. The substrate processing method according to claim 1, wherein the dry gas is an inert gas, and the relative humidity of the dry gas is not more than the relative humidity of the atmosphere.

15. The substrate processing method according to claim 1, wherein a replenishing liquid for the liquid on the substrate surface is supplied to the substrate surface at an anterior position in the direction of the movement of the gas/liquid suction nozzle relative to the substrate.

16. A substrate processing apparatus for drying a substrate surface which is wet with a liquid, comprising:
a gas/liquid suction nozzle, disposed opposite the substrate surface, for removing the liquid from the substrate surface and sucking the liquid together with its surrounding gas;
a dry gas supply nozzle for blowing a dry gas toward that area of the substrate surface from which the liquid has been removed; and
a movement mechanism for relatively moving the gas/liquid suction nozzle and the substrate parallel to each other and for relatively moving the dry gas supply nozzle and the substrate parallel to each other.

17. The substrate processing apparatus according to claim 16, wherein the gas/liquid suction nozzle and the dry gas supply nozzle are provided in a nozzle unit, and the movement mechanism is configured to move the nozzle unit parallel to the substrate.

18. The substrate processing apparatus according to claim 16, further comprising a liquid supply nozzle for supplying a liquid toward the substrate surface at a position posterior to the gas/liquid suction nozzle and anterior to the dry gas supply nozzle in the direction of their movement relative to the substrate.

19. The substrate processing apparatus according to claim 18, wherein the gas/liquid suction nozzle, the dry gas supply nozzle and the liquid supply nozzle are provided in a nozzle unit, and the movement mechanism is configured to move the nozzle unit parallel to the substrate.

20. The substrate processing apparatus according to claim 16, further comprising an organic solvent supply nozzle for supplying a water-soluble organic solvent to the substrate surface at a position posterior to the gas/liquid suction nozzle in the direction of its movement relative to the substrate.

21. The substrate processing apparatus according to claim 20, wherein the gas/liquid suction nozzle, the dry gas supply nozzle and the organic solvent supply nozzle are provided in a nozzle unit, and the movement mechanism is configured to move the nozzle unit parallel to the substrate.

22. The substrate processing apparatus according to claim 20, wherein the organic solvent supply nozzle is inclined at 45° to 90° with respect to the substrate surface.

23. The substrate processing apparatus according to claim 16, further comprising a replenishing liquid nozzle for supplying a replenishing liquid for the liquid on the substrate surface to the substrate surface at an anterior position in the direction of the movement of the gas/liquid suction nozzle relative to the substrate.

24. The substrate processing apparatus according to claim 16, wherein the gas/liquid suction nozzle is provided plurally, and the gas/liquid suction nozzles have slit-like suction openings arranged in series.
